(19) United States
(12) Patent Application Publication
(10) Pub. No.: US 2007/0017637 A1
(43) Pub. Date: Jan. 25, 2007

(54) Inductively coupled plasma processing apparatus

(76) Inventors: Kyu Sung Lee, Yongin-si (KR); Han Ki Kim, Yongin-si (KR); Do Geun Kim, Yongin-si (KR); Myoung Soo Kim, Yongin-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/489,656

(22) Filed: Jul. 18, 2006

(30) Foreign Application Priority Data
Jul. 20, 2005 (KR) 10-2005-66024

(51) Int. Cl. C23F 1/00; C23C 16/00

(52) U.S. Cl. 156/345.48; 118/723 I

(57) ABSTRACT

An inductively coupled plasma processing apparatus is disclosed. The inductively coupled plasma processing apparatus includes a reaction chamber, a substrate holder for forming a plasma space in the reaction chamber and for supporting a processing substrate therein, a shield provided at the lateral side of the substrate holder, a plurality of openings formed below the substrate, and a linear antenna in the lower portion of the reaction chamber to which a high frequency power signal is applied. Thus, the inductively coupled plasma processing apparatus can uniformly distribute the density of the plasma so that a large-sized flat panel display can be implemented.

### CROSS-REFERENCE TO RELATED APPLICATIONS

This application claims the benefit of Korean Patent Application No. 2005-66024, filed on Jul. 20, 2005, in the Korean Intellectual Property Office, the disclosure of which is incorporated herein by reference.

### BACKGROUND OF THE INVENTION

1. Field of the Invention

The present invention relates to an inductively coupled plasma processing apparatus, and more particularly, to an inductively coupled plasma processing apparatus having a process gas introducing opening formed in the lower center and lateral sides thereof and a linear antenna such that density of plasma is symmetrically and uniformly distributed over the central portion and outer side.

2. Description of the Related Art

Some flat panel display devices are characterized as organic display devices, while others are characterized as inorganic display devices, according to what type of materials are used. Plasma display panels (PDPs) and field emission displays (FEDs) tend to be inorganic displays, and liquid crystal displays (LCDs) and organic light emitting displays (OLEDs) tend to be organic displays.

Plasma is ionized gas and comprises positive ions, negative ions, electrons, excited atoms, molecules, and radicals with high chemical activity. Since the plasma has very different electrical and thermal characteristics from other gases, it is considered a fourth state of matter. Since plasma contains ionized gas, plasma is utilized in semiconductor manufacturing processing where a plasma is accelerated using an electric field or a magnetic field to perform etching of or vapor deposition on a semiconductor substrate.

An inductively coupled plasma processing apparatus includes a reaction chamber in a low pressure atmosphere, a sheath, formed in the reaction chamber, a lower electrode to which high frequency electric power signal is supplied, and a high frequency antenna installed in the outer side of the reaction chamber. Moreover, the inside of the inductively coupled plasma processing apparatus is sealed.

A plasma manufacturing method using the inductively coupled plasma processing apparatus will be described. Firstly, processing gas is introduced into the reaction chamber. At that time, the high frequency antenna disposed near a window wall above the reaction chamber is driven with the frequency electric power signal so as to generate plasma so that an inductive magnetic field is generated in the vertical direction of the antenna. By doing so, the inductive electric field generates an electric field. The processing gas ionizes because of the inductive electric field generating a plasma.

In some inductively coupled plasma processing devices, plasma can be generated by an inductive electric field as well as a capacitive electric field between the high frequency antenna and the inside of the reaction chamber. In the inductively coupled plasma processing apparatus, negative bias is applied to the substrate by biasing the lower electrode in the vicinity of the high frequency antenna, that is, a substrate holder. By doing so, vertical capacitance is generated in the reaction chamber. The capacitance field is more uniformly distributed because of the plasma due to the capacitive electric field in the reaction chamber.

However, a conventional inductively coupled plasma processing apparatus generates an asymmetry between the capacitive electric field and the inductive magnetic field because of the antenna structure, such that the density distribution of the plasma in the central portion of the reaction chamber is different from that of the plasma in the outer portion of the reaction chamber.

### SUMMARY OF THE INVENTION

Accordingly, embodiments provide an inductively coupled plasma processing apparatus capable of making the density distribution of plasma in the central portion and the outer portion of a reaction chamber substantially symmetric and substantially uniform.

One embodiment is an inductively coupled plasma processing apparatus including a reaction chamber, a substrate holder positioned so as to form a plasma space in the reaction chamber and configured to support a substrate therein, a shield positioned adjacent to the substrate holder, a plurality of openings formed in the reaction chamber below the substrate holder, and a linear antenna positioned beneath the reaction chamber, where the linear antenna is configured to receive a high frequency power signal.

Another embodiment is an inductively coupled plasma processing apparatus including means for containing a reaction, means for supporting a substrate positioned so as to form a plasma space in the means for containing a reaction, means for isolating a plasma positioned adjacent to the means for supporting the substrate, means for introducing gas into the means for containing a reaction, the means for introducing a gas positioned into the means for containing a reaction below the means for supporting a substrate, and means for transmitting positioned beneath the means for containing a reaction, where the means for transmitting is configured to receive a high frequency power signal.

Another embodiment is an inductively coupled plasma processing apparatus including a reaction chamber, a substrate holder positioned in the reaction chamber so as to form a plasma space, and configured to support a substrate, where the reaction chamber has a plurality of openings below the substrate holder, and the openings are configured to permit entry of a processing gas into the reaction chamber, a shield positioned adjacent to the substrate holder, and a linear antenna positioned beneath the reaction chamber, the linear antenna configured to receive a high frequency power signal.

### BRIEF DESCRIPTION OF THE DRAWINGS

These and/or other objects and advantages of the invention will become apparent and more readily appreciated from the following description of the preferred embodiments, taken in conjunction with the accompanying drawings of which:

FIG. 1 is a cross-sectional view of an inductively coupled plasma processing apparatus according to an embodiment of the present invention; and

FIG. 2 is a plan view of the inductively coupled plasma processing apparatus according to an embodiment of the present invention.

### DETAILED DESCRIPTION OF CERTAIN INVENTIVE ASPECTS

Hereinafter, certain inventive aspects will be described with reference to the attached drawings.

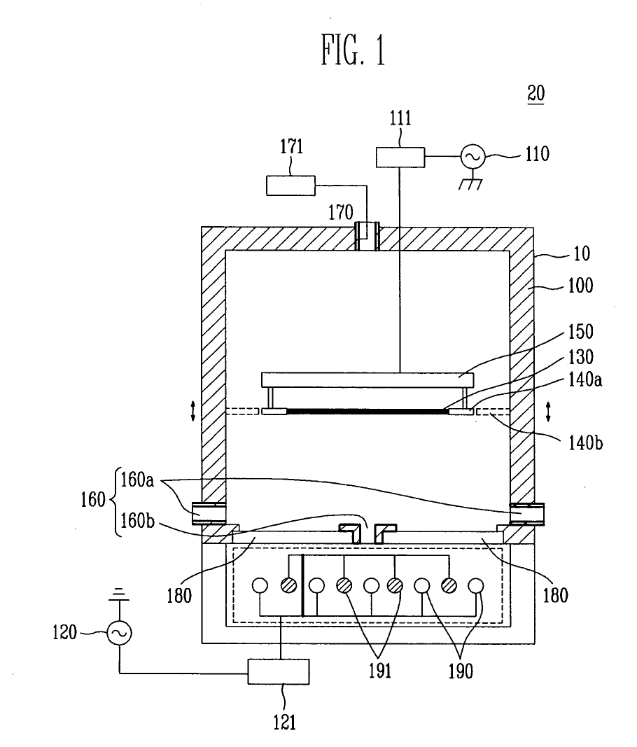

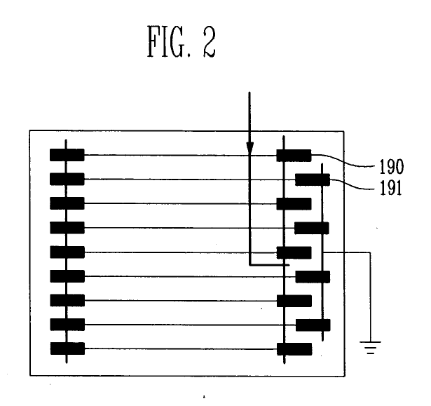

FIG. 1 is a cross-sectional view of an inductively coupled plasma processing apparatus according to one embodiment, and FIG. 2 is a plan view of the inductively coupled plasma processing apparatus according to one embodiment.

Referring to FIGS. 1 and 2, an inductively coupled plasma processing apparatus 20 includes an reaction chamber 10, a substrate holder 140a configured to support a processing substrate 130 disposed in a plasma processing space formed in the reaction chamber 10, a shield 140b and a lower electrode 150 provided adjacent to the substrate holder 140a, a plurality of processing gas introducing openings 160a and 160b at the lower center and the side portions of the reaction chamber 10, a processing gas discharge port 170 formed in the reaction chamber 10 above the processing substrate 130, a window 180 at the lower side of the reaction chamber 10, and a linear antennas 190 and 191, separated from the reaction chamber 10 by the window 180 and positioned below the window 180.

The reaction chamber 10 consists of a sealed container 100 within which the plasma processing occurs. The container 100 may be made of a dielectric material comprising aluminum (Al), alumina (Al₂O₃), or aluminum nitride (AlN), but is not limited to these materials.

The reaction chamber 10 includes a lower electrode 150 supported by the processing substrate 130, the substrate holder 140a, and the shield 140b.

The lower electrode 150 is a plate to which a bias voltage is applied, wherein a high or medium frequency power signal is applied through a matching circuit 111. The signal may, for example, have a frequency of 13.56 MHz, tens of Hz, or may be from hundreds of Hz to hundreds of MHz. The matching circuit 111 can effectively distribute the electric power signal and can minimize power loss.

In this embodiment the shield 140b is formed at the lateral side of the substrate holder 140a, and has a mesh structure or a structure with holes. The shield 140b prevents plasma from flowing to the upper side of the processing substrate 130 during plasma processing.

The substrate holder 140a and the shield 140b can move up and down. So as to adjust the distance between the processing substrate 130 and plasma the substrate holder 140a and the shield 140b are configured to be adjustable such that they can be moved up and down. As a result, the substrate holder 140a and the shield 140b can process plasma without damage of the surface of the processing substrate 130. Additionally, transferring and withdrawing are simplified during plasma processing of the processing substrate 130, and the upward organic vapor deposition is improved.

Openings 160b and 160a are formed in the lower central portion and the lateral side, respectively, of the container 100. The processing gas is supplied into the reaction chamber 10 through the openings 160a and 160b. By doing so, density of plasma in the reaction chamber 10 is symmetrically and uniformly distributed across the central portion and the outer side portions of the reaction chamber 10. As the processing gas, for example, O₂, N₂, or Ar can be used. Pressure of the processing gas may be maintained 1 mTorr to 100 mTorr through the openings 160a and 160b.

The processing gas discharge port 170 may be formed in an area of the upper side of the reaction chamber 10, but is not limited to this. In some embodiments the processing gas discharge port 170 is formed above the processing substrate 130 to form uniform plasma. In order to form uniform discharge of the plasma, the processing gas discharge port 170 further includes a pumping port 171 configured to maintain uniform processing pressure and to easily discharge ionized molecules and ionized particles.

The window 180 forms a lower wall of the reaction chamber 10. The window 180 may be made of an insulator such as ceramic or quartz, but is not limited to these materials. The window 180 may be, for example, from about the same size of the processing substrate 130 to about one sixteenth the sized of the processing substrate 130. The window 180 can transfer electric field and magnetic field generated at the linear antennas 190 and 191 to the lower side of the processing substrate 130 to accelerate the plasma.

The linear antennas 190 and 191 are positioned near the lower side of the reaction chamber 10, and the linear antennas 190 and 191 are connected to the high frequency power signal source 120 via a matching circuit 121. The high frequency power signal source 120 applies a high frequency power signal to the linear antennas 190 and 191.

The linear antennas 190 and 191 extend beyond the outer edge of the processing substrate 130. The linear antennas 190 and 191 apply power to substantially the entire area of the processing substrate 130 so as to generate a uniform plasma.

Polarity of the high frequency power signal may be continuously changed. The high frequency power signal source 120 can apply frequency, for example, of from about 20 MHz to about 60 MHZ. In some embodiments, the high frequency power signal source is configured to apply a frequency of aobut 13.56 MHz, through the matching circuit 121.

The matching circuit 121 is configured to properly distribute the power and may minimize power loss.

In some embodiments described above, the openings 160b and 160a are formed in the lower central portion 160b and the lateral side 160a, respectively of the reaction chamber 10, but are not limited to these locations. Also the number of openings 160a and 160b may be varied.

Those skilled in the art will appreciate that the aforementioned inventive aspects can be applied to an active matrix organic light emitting diode (AMOLED), a liquid crystal display (LCD), a field emission display (FED), a plasma display panel (PDP), an electro-luminescent display (ELD), a laser induced thermal imaging (LITI), and a vacuum fluorescent display (VFD).

As described above, the processing gas introducing openings are formed in the lower central portion and the lateral side of the reaction chamber and the linear antennas are disposed at the lower side of the reaction chamber so that density of plasma can be symmetrically and uniformly distributed over the central portion and the outer side in the reaction chamber. By doing so, the efficiency of generating plasma is increased so that a plasma apparatus suitable for the surface processing of a large-sized flat panel display can be provided.

Moreover, surface properties and the work function of an anode are improved by uniform plasma so that an organic layer and charge transfer characteristics can be enhanced and efficiency in a whole vapor-deposition system can be improved.

Certain terms, such as above and below, implying orientation have been used herein. These terms are not meant to limit the invention, but rather to describe various embodiments. The orientation with which these terms are generally used is that which is depicted in the figures. It will be understood that other orientations and other relative arrangements fall within the scope of the inventive aspects of this application.

Although certain embodiments have been disclosed for illustrative purposes, those skilled in the art will appreciate that various modifications, additions and substitutions are possible, without departing from the scope and spirit of the invention.

What is claimed is:

1. An inductively coupled plasma processing apparatus comprising:
a reaction chamber;
a substrate holder positioned so as to form a plasma space in the reaction chamber and configured to support a substrate therein;
a shield positioned adjacent to the substrate holder;
a plurality of openings formed in the reaction chamber below the substrate holder; and
a linear antenna positioned beneath the reaction chamber, wherein the linear antenna is configured to receive a high frequency power signal.

2. The inductively coupled plasma processing apparatus of claim 1, wherein the linear antenna has a lateral dimension greater than the lateral dimension of the substrate.

3. The inductively coupled plasma processing apparatus of claim 1, wherein the shield has a mesh structure or a structure with holes.

4. The inductively coupled plasma processing apparatus of claim 3, wherein the shield is configured to substantially prevent plasma from flowing to a space above the substrate holder.

5. The inductively coupled plasma processing apparatus of claim 1, wherein the substrate holder and the shield are configured to be moveable up and down.

6. The inductively coupled plasma processing apparatus of claim 1, further comprising a window between the substrate holder and the linear antenna, wherein the window is formed from ceramic or quartz.

7. The inductively coupled plasma processing apparatus of claim 6, wherein the window has a dimension based on the dimensions of the substrate.

8. The inductively coupled plasma processing apparatus of claim 7, wherein the lateral dimension of the window is between about the lateral dimension of the substrate and about one sixteenth the lateral dimension of the substrate.

9. The inductively coupled plasma processing apparatus of claim 1, further comprising a gas discharge port above the substrate holder.

10. The inductively coupled plasma processing apparatus of claim 9, wherein the gas discharge port is connected to a pumping port.

11. The inductively coupled plasma processing apparatus of claim 1, wherein the apparatus is configured to process the substrate by a laser thermal transfer method.

12. An inductively coupled plasma processing apparatus comprising:
means for containing a reaction;
means for supporting a substrate positioned so as to form a plasma space in the means for containing a reaction;
means for isolating a plasma positioned adjacent to the means for supporting the substrate;
means for introducing gas into the means for containing a reaction, the means for introducing a gas positioned into the means for containing a reaction below the means for supporting a substrate; and
means for transmitting positioned beneath the means for containing a reaction, wherein the means for transmitting is configured to receive a high frequency power signal.

13. The apparatus of claim 12, further comprising means for moving the means for supporting a substrate and the means for isolating a plasma up and down.

14. The method of claim 12, further comprising means for processing the substrate by a laser thermal transfer method.

15. An inductively coupled plasma processing apparatus comprising:
a reaction chamber;
a substrate holder positioned in the reaction chamber so as to form a plasma space, and configured to support a substrate, wherein the reaction chamber has a plurality of openings below the substrate holder, and the openings are configured to permit entry of a processing gas into the reaction chamber;
a shield positioned adjacent to the substrate holder; and
a linear antenna positioned beneath the reaction chamber, the linear antenna configured to receive a high frequency power signal.

16. The inductively coupled plasma processing apparatus of claim 15, wherein the linear antenna has a lateral dimension greater than the lateral dimension of the substrate.

17. The inductively coupled plasma processing apparatus of claim 15, wherein the shield has a mesh structure or a structure with holes.

18. The inductively coupled plasma processing apparatus of claim 15, wherein the substrate holder and the shield are configured to be moveable up and down.

19. The inductively coupled plasma processing apparatus of claim 15, further comprising a window between the substrate holder and the linear antenna, wherein the window is formed from ceramic or quartz.

20. The inductively coupled plasma processing apparatus of claim 15, further comprising a gas discharge port above the substrate holder.
